(19) United States
(12) Patent Application Publication
(10) Pub. No.: US 2013/0268217 A1
(43) Pub. Date: Oct. 10, 2013

(54) METHOD AND APPARATUS FOR DETECTING ABNORMALITY OF A CAPACITOR

(71) Applicants: Sang Il Kim, Gyeonggi-do (KR); Chang Hyun Kim, Gyeonggi-do (KR); Kwang Woon Kim, Gyeonggi-do (KR)

(72) Inventors: Sang Il Kim, Gyeonggi-do (KR); Chang Hyun Kim, Gyeonggi-do (KR); Kwang Woon Kim, Gyeonggi-do (KR)

(73) Assignee: DOOSAN INFRACORE CO., LTD., Incheon (KR)

(21) Appl. No.: 13/993,571

(22) PCT Filed: Dec. 13, 2011
(86) PCT No.: PCT/KR11/09593

§ 371 Date: Jun. 12, 2013

(30) Foreign Application Priority Data
Dec. 14, 2010 (KR) 10-2010-0127729

(51) Int. Cl. G01R 31/36

(52) U.S. Cl. CPC G01R 31/3627
USPC 702/58; 324/548

(57) ABSTRACT

The present disclosure provides a capacitor abnormality detection method and detection apparatus for accurately detecting an abnormality of an individual capacitor in a circuit in which two or more capacitors are connected in series at a low cost, and the capacitor abnormality detection apparatus includes: a measuring unit configured to measure capacitance of the circuit from both ends of the circuit; a storage unit configured to store the measured capacitance of the circuit and hours of use of the circuit during the measurement; and a determining unit configured to determine whether an abnormality is generated in at least one capacitor configuring the circuit by comparing the measured capacitance of the circuit and predetermined expected capacitance.

### CROSS-REFERENCE TO RELATED APPLICATION

This Application is a Section 371 National Stage Application of International Application No. PCT/KR2011/009593, filed Dec. 13, 2011 and published, not in English, as WO2012/081892 on Jun. 21, 2012.

### FIELD OF THE DISCLOSURE

The present disclosure relates to a method and an apparatus for detecting an abnormality of a capacitor, and more particularly, to a method and an apparatus for detecting an abnormality of at least one capacitor configuring a circuit in which two or more capacitors are connected in series.

### BACKGROUND OF THE DISCLOSURE

In a capacitor circuit configured by connecting two or more capacitors (or batteries) in series, when an abnormality, such as a short circuit, is generated in any one among individual capacitors in the capacitor circuit, the abnormality exerts an influence on the whole circuit, so that a technique for detecting an abnormality of the individual capacitor for the circuit including the plurality of capacitors is necessary.

As the aforementioned technique, a method of determining an abnormality of each capacitor by monitoring all of the individual capacitors configuring the capacitor circuit is present. Further, as another technique, there is a method of measuring entire capacitance of the capacitor circuit, and determining that an abnormality is generated in the capacitor when it is determined that the measured capacitance has a value equal to or smaller than a predetermined value.

The discussion above is merely provided for general background information and is not intended to be used as an aid in determining the scope of the claimed subject matter.

### SUMMARY

This summary and the abstract are provided to introduce a selection of concepts in a simplified form that are further described below in the Detailed Description. The summary and the abstract are not intended to identify key features or essential features of the claimed subject matter, nor are they intended to be used as an aid in determining the scope of the claimed subject matter.

However, in a case of the former among the related techniques, there is a problem in that high priced-equipment which mounts many components for monitoring each capacitor is necessary. In a case of the latter, when the individual capacitor is short circuited to generate an abnormality, the entire capacitance of the capacitor circuit is increased, so that there is a problem in that the short circuit of the individual capacitor is not detected. Further, even though the abnormality of the capacitor is detected by a corresponding method, the abnormality may be detected only in a state where an abnormality is generated in a plurality of capacitors, so that there is a problem in that it is impossible to respond at an initial stage of when the abnormality of the capacitor starts, and even then it may be only possible to determine the decrepitude of the capacitor.

An embodiment of the present disclosure is to provide a method and an apparatus for detecting an abnormality of a capacitor, which accurately detect an abnormality of an individual capacitor in a circuit in which two or more capacitors are connected in series at a low cost.

Another embodiment of the present disclosure is to provide a method and an apparatus for detecting an abnormality of a capacitor, which accurately estimate the number of individual capacitors, in which an abnormality is generated, in a circuit in which two or more capacitors are connected in series at a low cost.

In order to achieve the object, an embodiment of the present disclosure provides a method of detecting an abnormality of a capacitor in a circuit, in which two or more capacitors are connected in series, the method including: measuring capacitance of the circuit from both ends of the circuit; storing the measured capacitance of the circuit and hours of use of the circuit during the measurement in a storage unit; calculating a decrease rate of the capacitance according to hours of use of the circuit based on capacitance data of the circuit and data of the hours of use of the circuit stored according to a plurality of times of measurement; and determining whether an abnormality is generated in at least one capacitor configuring the circuit by comparing the measured capacitance of the circuit and capacitance expected according to the calculated decrease rate.

The determining of the method of detecting the abnormality of the capacitor may include determining that the abnormality is generated in the capacitor in a case where the measured capacitance of the circuit is beyond a predetermined range from the capacitance expected according to the calculated decrease rate.

The method of detecting the abnormality of the capacitor may further include: estimating the number of abnormalities by calculating average capacitance of unit capacitors configuring the circuit based on the capacitance expected according to the calculated decrease rate, and estimating the number of capacitors in which the abnormality is generated based on the calculated average capacitance, the number of capacitors configuring the circuit, and the measured capacitance of the circuit.

In order to achieve the object, an embodiment of the present disclosure provides another method of detecting an abnormality of a capacitor in a circuit in which two or more capacitors are connected in series, the method including: measuring capacitance of the circuit from both ends of the circuit; storing the capacitance of the circuit according to a plurality of times of measurement and hours of use of the circuit during the measurement in a storage unit; and determining whether the measured capacitance of the circuit is larger than capacitance of the circuit which is measured and stored just before the measurement by a predetermined value, and determining that the abnormality is generated in at least one capacitor configuring the circuit when it is determined that the measured capacitance of the circuit is larger than capacitance of the circuit which is measured and stored just before the measurement by the predetermined value.

In order to achieve the object, an embodiment of the present disclosure provides an apparatus for detecting an abnormality of a capacitor in a circuit in which two or more capacitors are connected in series, the apparatus including: a measuring unit configured to measure capacitance of the circuit from both ends of the circuit; a storage unit configured to store the measured capacitance of the circuit and hours of use of the circuit during the measurement; and a determining unit configured to determine whether an abnormality is generated in at least one capacitor configuring the circuit by comparing the measured capacitance of the circuit and predetermined expected capacitance.

In the apparatus for detecting an abnormality of a capacitor according to the present disclosure, the predetermined expected capacitance may be capacitance of the circuit measured and stored just before the measurement of the capacitance, and the determining unit may determine that the abnormality is generated in said at least one capacitor by determining whether the measured capacitance of the circuit is larger than the capacitance of the circuit measured and stored just before the measurement of the capacitance by a predetermined value.

Further, the apparatus for detecting the abnormality of the capacitor may further include a calculation unit configured to calculate a decrease rate of the capacitance according to hours of use of the circuit based on capacitance data of the circuit and data of the hours of use of the circuit stored according to a plurality of times of measurement, in which the determining unit may compare the measured capacitance of the circuit and the expected capacitance.

Further, the apparatus for detecting the abnormality of the capacitor may further include: a calculation unit configured to calculate a decrease rate of the capacitance according to hours of use of the circuit based on capacitance data of the circuit and data of the hours of use of the circuit stored according to a plurality of times of measurement; and an abnormality number estimating unit configured to calculate average capacitance of unit capacitors configuring the circuit based on the capacitance expected according to the calculated decrease rate, and estimates the number of capacitors in which the abnormality is generated based on the calculated average capacitance, the number of capacitors configuring the circuit, and the measured capacitance of the circuit.

According to the aforementioned technical solutions, it is possible to accurately detect an abnormality of an individual capacitor in a circuit in which two or more capacitors are connected in series at a low cost. Further, it is possible to accurately estimate the number of individual capacitors, in which an abnormality is generated, in a circuit in which two or more capacitors are connected in series at a low cost.

### DESCRIPTION OF THE DRAWINGS

FIG. 1 is a diagram illustrating a circuit in which a plurality of capacitors is connected in series, and an equivalent circuit of one capacitor.

FIG. 2A is a graph illustrating a change in capacitance and ESR (Equivalent Series Resistance) according to degradation.

FIG. 2B is a graph illustrating a change in capacitance and ESR according to a short circuit of a capacitor.

FIG. 3 is a block diagram schematically illustrating a capacitor abnormality detection apparatus 100 according to an exemplary embodiment of the present disclosure.

FIG. 4 is a flowchart for describing a capacitor abnormality detection method according to an exemplary embodiment of the present disclosure.

Description of Main Reference Numerals of Drawings

| | |
|---|---|
| 100: Capacitor abnormality detection apparatus | |
| 110: Measuring unit | 120: Storage unit |
| 130: Inclination calculation unit | 140: Determining unit |
| 150: Abnormality number estimating unit | 160: Notifying unit |

### DETAILED DESCRIPTION

Hereinafter, a capacitor abnormality detection apparatus and detection method according to an exemplary embodiment of the present disclosure will be described in detail with reference to the accompanying drawings.

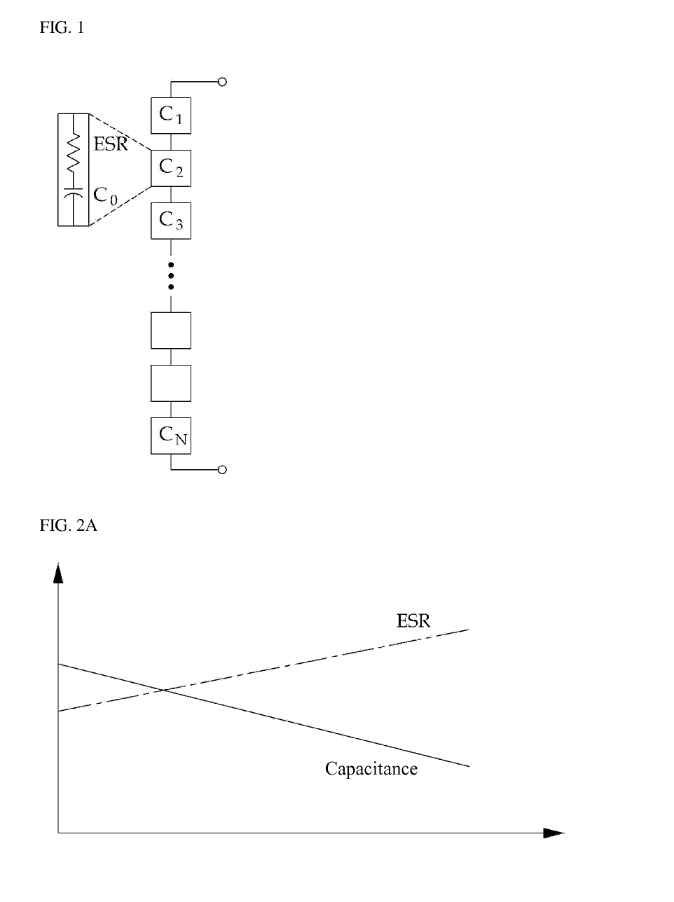

FIG. 1 illustrates a circuit in which a plurality of capacitors C₁, C₂, C₃, . . . , and C_{N} is connected in series, and an equivalent circuit of one capacitor C₂ among the plurality of capacitors C₁, C₂, C₃, . . . , and C_{N}. A capacitor device, such as a battery, actually includes internal resistance (ESR), which is illustrated as an equivalent circuit as illustrated in FIG. 1.

The total capacitance Cₜₒₜ of the circuit in which the plurality of capacitors is connected in series is decreased as the number of capacitors which are connected in series is increased, which is expressed by Equation below.

$$\frac{1}{{C}_{101}} = \frac{1}{{C}_{1}} + \frac{1}{{C}_{2}} + … + \frac{1}{{C}_{N - 1}} + \frac{1}{{C}_{N}} \qquad [ Equation 1 ]$$

Further, Equation 1 may be changed to Equation below.

$${C}_{101} = \frac{{C}_{0}}{{N}_{1}} \qquad [ Equation 2 ]$$

In Equation 2, C₀ is average capacitance of a unit capacitance, and N is the number of capacitors which are connected in series.

In a case where an abnormality is generated in some capacitors among the plurality of capacitors due to a short circuit and the like, entire capacitance Cₜₒₜ_{_{—}}ₛₕₒᵣₜ of the circuit is increased. This may be expressed by Equation below, and herein, M represents the number of capacitors in which an abnormality is generated.

$${C}_{101} = \frac{{C}_{0}}{N} < {C}_{101 \_ short} = \frac{{C}_{0}}{N - M} \qquad [ Equation 3 ]$$

Further, the number M of capacitors in which the abnormality is generated may be estimated from Equation 3, which may be expressed by Equation below.

$$M = N - \frac{{C}_{0}}{{C}_{101 \_ short}} \qquad [ Equation 4 ]$$

An embodiment of the present disclosure is conceived from the understanding of the fact that the entire capacitance of the circuit is increased in a case where an abnormality is generated in the some capacitors due to a short circuit and the like, and the fact that the number M of capacitors in which the abnormality is generated may be estimated when the number N of all capacitors of the circuit, the average capacitance C₀ of the unit capacitor, and the value of the entire capacitance Cₜₒₜ_{_{—}}ₛₕₒᵣₜ of the circuit in a case where the abnormality is generated in the capacitors are known as described above.

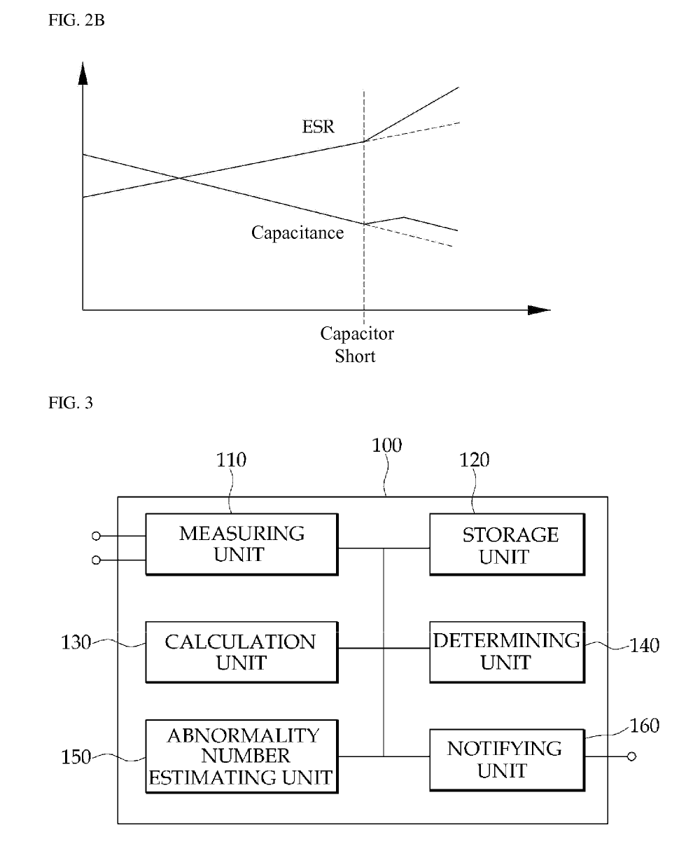

FIG. 2A illustrates a change in entire capacitance and ESR (Equivalent Series Resistance) according to degradation, and FIG. 2B illustrates a change in entire capacitance and ESR according to a short circuit of some capacitors. Referring to FIG. 2A, it can be seen that the entire capacitance of the circuit is decreased at a uniform inclination and the ESR is increased at a uniform inclination according to degradation of the circuit. Contrary to this, referring to FIG. 2B, it can be seen that the entire capacitance is increased and an increase rate of the ESR is increased at a time at which some capacitors of the circuit is short circuited.

Hereinafter, a configuration of a capacitor abnormality detection apparatus 100 according to an exemplary embodiment of the present disclosure will be described with reference to FIG. 3. The capacitor abnormality detection apparatus 100 according to the present disclosure includes a measuring unit 110, a storage unit 120, a calculation unit 130, a determining unit 140, an abnormality number estimating unit 150, and a notifying unit 160.

The measuring unit 110 is configured to measure entire capacitance of the circuit from both ends of the circuit in which two or more capacitors are connected in series. For example, the capacitance of the circuit may be obtained by measuring a change rate of a voltage according to a time while constant current flows by the measuring unit 110. However, the method of measuring the capacitance is not limited thereto, and any method in the related art for measuring capacitance of a circuit may be used.

The storage unit 120 is configured to store the capacitance of the circuit measured by the measuring unit 110 and hours of use of the circuit (charging/discharging hours) during the measurement. The storage unit 200 may include any medium capable of storing data, and is not limited to a specific storage medium.

The calculation unit 130 is configured to calculate a decrease rate of the capacitance according to the hours of use of the circuit based on capacitance data of the circuit and data of the hours of use of the circuit stored according to a plurality of times of measurement.

The determining unit 140 is configured to determine where an abnormality is generated in at least one capacitor configuring the circuit. For example, the determining unit 140 may determine where an abnormality is generated in the individual capacitor configuring the circuit by determining whether the measured capacitance of the circuit is beyond a predetermined range from capacitance expected according to the calculated decrease rate, or determining whether the measured capacitance of the circuit is larger than capacitance of the circuit which is measured and stored just before the measurement by a predetermined value.

The abnormality number estimating unit 150 is configured to calculate average capacitance of the unit capacitors configuring the circuit based on the capacitance expected according to the calculated decrease rate, and estimate the number of capacitors in which the abnormality is generated based on the calculated average capacitance, the number of capacitors configuring the circuit, and the measured capacitance of the circuit according to Equation 4.

The notifying unit 160 is configured to notify a user of the generation of the abnormality in the capacitor or the number of capacitors in which the abnormality is generated in a case where it is determined that the abnormality of the capacitor is generated by the determining unit 140, or the number of capacitors in which the abnormality is generated is estimated by the abnormality number estimating unit 150. For example, a method by a screen display or a method by a sound may be used as a notifying method, and a transmission of a signal representing the generation of the abnormality of the capacitor or the number of capacitors in which the abnormality is generated to an external device may also be used as a notifying method.

According to the aforementioned capacitor abnormality detection apparatus 100, it is possible to accurately detect an abnormality of the individual capacitor in the circuit in which two or more capacitors are connected in series at a low cost, and it is also possible to predict the number of individual capacitors in which an abnormality is generated.

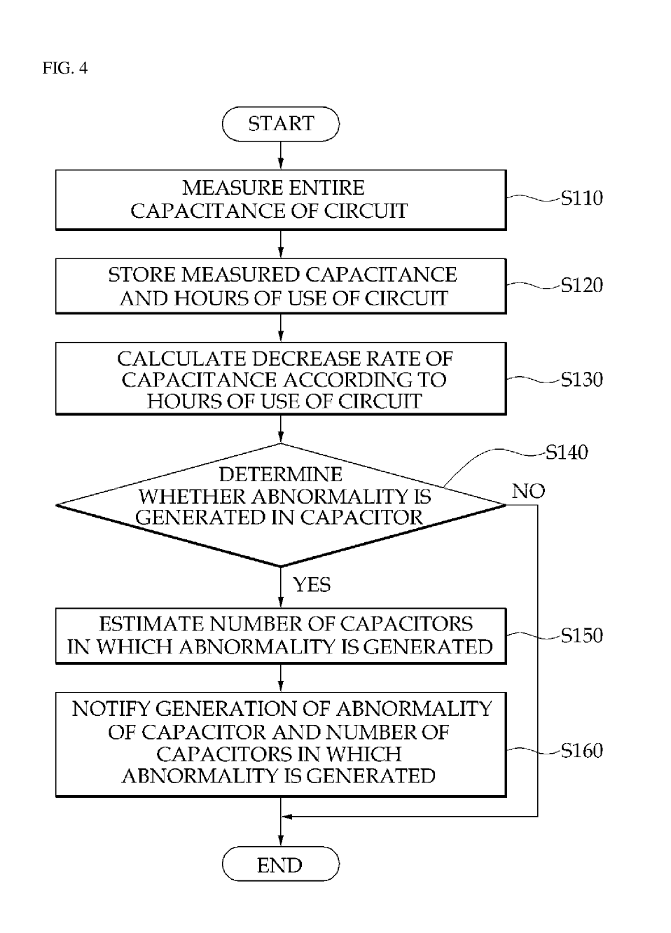

Hereinafter, a capacitor abnormality detecting method according to an exemplary embodiment of the present disclosure will be described with reference to FIG. 4.

First, entire capacitance of the circuit from both ends of the circuit is measured (S110), and the measured capacitance and hours of use of the circuit (charging/discharging hours) during the measurement is stored in the storage unit (S 120).

Then, a decrease rate of the capacitance according to the hours of use of the circuit is calculated based on capacitance data of the circuit stored according to the plurality of times of measurement and data of the hours of use of the circuit (S 130), and whether an abnormality is generated in at least one capacitor configuring the circuit is determined (S 140). For example, whether the abnormality is generated in the capacitor may be determined by determining whether the measured capacitance of the circuit is beyond a predetermined range from capacitance expected according to the calculated decrease rate, or determining whether the measured capacitance of the circuit is larger than capacitance of the circuit which is measured and stored just before the measurement by a predetermined value.

In a case where it is determined that the abnormality is generated in the capacitor (“YES” in S140), average capacitance of the unit capacitors configuring the circuit is calculated based on the capacitance expected according to the calculated decrease rate, and the number of capacitors in which the abnormality is generated is estimated based on the calculated average capacitance, the number of capacitors configuring the circuit, and the measured capacitance of the circuit according to Equation 4 (S150). Then, the generation of the abnormality in the capacitor and the number of capacitors in which the abnormality is generated is notified to the user (S160).

According to the aforementioned capacitor abnormality detecting method, it is possible to accurately detect an abnormality of the individual capacitor in the circuit in which two or more capacitors are connected in series at a low cost, and it is also possible to predict the number of individual capacitors in which an abnormality is generated.

According to the aforementioned technical solutions, it is possible to accurately detect an abnormality of the individual capacitor in the circuit in which two or more capacitors are connected in series at a low cost. Further, it is possible to accurately estimate the number of individual capacitors in which an abnormality is generated in the circuit in which two or more capacitors are connected in series at a low cost.

Although the present disclosure has been described with reference to exemplary and preferred embodiments, workers skilled in the art will recognize that changes may be made in form and detail without departing from the spirit and scope of the disclosure.

1. A method of detecting an abnormality of a capacitor in a circuit in which two or more capacitors are connected in series, the method comprising:
measuring capacitance of the circuit from both ends of the circuit;
storing the measured capacitance of the circuit and hours of use of the circuit during the measurement in a storage unit;
calculating a decrease rate of the capacitance according to the hours of use of the circuit based on capacitance data of the circuit and data of the hours of use of the circuit stored according to a plurality of times of measurement; and
determining whether an abnormality is generated in at least one capacitor configuring the circuit by comparing the measured capacitance of the circuit and capacitance expected according to the calculated decrease rate.

2. The method of claim 1, wherein the determining includes determining that the abnormality is generated in the capacitor in a case where the measured capacitance of the circuit is beyond a predetermined range from the capacitance expected according to the calculated decrease rate.

3. The method of claim 1, further comprising:
estimating the number of abnormalities by calculating average capacitance of unit capacitors configuring the circuit based on the capacitance expected according to the calculated decrease rate, and estimating the number of capacitors in which the abnormality is generated based on the calculated average capacitance, the number of capacitors configuring the circuit, and the measured capacitance of the circuit.

4. A method of detecting an abnormality of a capacitor in a circuit in which two or more capacitors are connected in series, the method comprising:
measuring capacitance of the circuit from both ends of the circuit;
storing the capacitance of the circuit according to a plurality of times of measurement and hours of use of the circuit during the measurement in a storage unit; and
determining whether the measured capacitance of the circuit is larger than capacitance of the circuit which is measured and stored just before the measurement by a predetermined value, and determining that the abnormality is generated in at least one capacitor configuring the circuit when it is determined that the measured capacitance of the circuit is larger than capacitance of the circuit which is measured and stored just before the measurement by the predetermined value.

5. An apparatus for detecting an abnormality of a capacitor in a circuit in which two or more capacitors are connected in series, the apparatus comprising:
a measuring unit configured to measure capacitance of the circuit from both ends of the circuit;
a storage unit configured to store the measured capacitance of the circuit and hours of use of the circuit during the measurement; and
a determining unit configured to determine whether an abnormality is generated in at least one capacitor configuring the circuit by comparing the measured capacitance of the circuit and predetermined expected capacitance.

6. The apparatus of claim 5, wherein the predetermined expected capacitance is capacitance of the circuit measured and stored just before the measurement of the capacitance, and
the determining unit determines that the abnormality is generated in said at least one capacitor by determining whether the measured capacitance of the circuit is larger than the capacitance of the circuit measured and stored just before the measurement of the capacitance by a predetermined value.

7. The apparatus of claim 5, further comprising:
a calculation unit configured to calculate a decrease rate of the capacitance according to hours of use of the circuit based on capacitance data of the circuit and data of the hours of use of the circuit stored according to a plurality of times of measurement,
wherein the determining unit compares the measured capacitance of the circuit and the expected capacitance.

8. The apparatus of claim 6, further comprising:
a calculation unit configured to calculate a decrease rate of the capacitance according to hours of use of the circuit based on capacitance data of the circuit and data of the hours of use of the circuit stored according to a plurality of times of measurement; and
an abnormality number estimating unit configured to calculate average capacitance of unit capacitors configuring the circuit based on the capacitance expected according to the calculated decrease rate, and estimate the number of capacitors in which the abnormality is generated based on the calculated average capacitance, the number of capacitors configuring the circuit, and the measured capacitance of the circuit.
